(19) United States
(12) Patent Application Publication
(10) Pub. No.: US 2026/0190597 A1
(43) Pub. Date: Jul. 2, 2026

(54) Method for Mitigating Substrate Cracking in a Flexible Perovskite Solar Cell and Resulting Substrate

(71) Applicant: Brown University, Providence, RI (US)

(72) Inventors: Nitin P. Padture, Providence, RI (US); Haneesh Kesari, Barrington, RI (US); Anush Ranka, Providence, RI (US)

(21) Appl. No.: 19/439,115

(22) Filed: Jan. 2, 2026

Related U.S. Application Data
(60) Provisional application No. 63/741,236, filed on Jan. 2, 2025.

(51) Int. Cl. H10K 30/80; H10K 30/10; H10K 30/50

(52) U.S. Cl. CPC H10K 30/80; H10K 30/10; H10K 30/50

(57) ABSTRACT

A method for mitigating substrate cracking in a flexible perovskite solar cell is provided including the use of an interlayer between an electrode and the substrate.

### RELATED APPLICATION DATA

This application claims priority to U.S. provisional application No. 63/741,236, filed Jan. 2, 2025 which is hereby incorporated herein by reference in its entirety for all purposes.

### STATEMENT OF GOVERNMENT INTERESTS

This invention was made with government support under DE-EE0009511 awarded by Department of Energy. The government has certain rights in the invention.

### FIELD

The present disclosure is directed to flexible perovskite solar cells.

### BACKGROUND

Perovskite solar cells (PSC) are a promising new thin-film photovoltaic (PV) technology, with the potential for being low-cost and small-carbon-footprint. See N. P. Padture, The Promise of Metal-Halide-Perovskite Solar Photovoltaics: A Brief Review. MRS Bulletin 48, 983-998 (2023). At the heart of PSCs is the metal halide perovskite (MHP) thin-film light absorber, which is amenable to solution- or vapor-deposition at moderate temperatures (<150° C.). This allows PSCs to be fabricated on thin polymer substrates, resulting in lightweight, flexible PV devices. See Y. Gao et al., Flexible Perovskite Solar Cells: From Materials and Device Architectures to Applications. ACS Energy Letters 7, 1412-1445 (2022); X. Li et al., Progress and Challenges Toward Effective Flexible Perovskite Solar Cells. Nano-Micro Letters 15, 206 (2023); J. Liu et al., Evolutionary manufacturing approaches for advancing flexible perovskite solar cells. Joule 8, 944-969 (2024). There is growing interest in flexible PSCs (f-PSCs) because they are uniquely suited for outdoor consumer applications such as portable chargers, wearables, tents, backpacks, deployable rollups, cars, drones, sails, etc., indoor internet-of-things (IoT) applications, (see A. Chakraborty et al., Photovoltaics for Indoor Energy Harvesting. Nano Energy 128, 109932 (2024)) and space applications (see Y. Tu et al., Perovskite Solar Cells for Space Applications: Progress and Challenges. Advanced Materials 33, 2006545 (2021)). Alternatively, one can envision taking advantage of the lightweightness and manufacturability (e.g. roll-to-roll) of f-PSCs for residential rooftops (see P. Holzhey et al., Toward commercialization with lightweight, flexible perovskite solar cells for residential photovoltaics. Joule 7, 257-271 (2023)) and utility-scale PV applications (see Q. Dong et al., Flexible Perovskite Solar Cells with Simultaneously Improved Efficiency, Operational Stability, and Mechanical Reliability. Joule 5, 1587-1601 (2021) and L. McGovern et al., A techno-economic perspective on rigid and flexible perovskite solar modules. Sustainable Energy and Fuels 7, 5259-5270 (2023). However, f-PSCs are subjected to much higher applied mechanical stresses (stretching, bending, twisting) during manufacturing and in-service, compared to their rigid counterparts fabricated on glass substrates. See Z. Dai et al., Dual-interface reinforced flexible perovskite solar cells for enhanced performance and mechanical reliability. Advanced Materials 34, 2205301 (2022) and Z. Dai et al., Challenges and Opportunities for the Mechanical Reliability of Metal-Halide Perovskites and Photovoltaics. Nature Energy 8, 1319-1327 (2023). While numerous studies report cracking of the different layers within f-PSCs in bending, (see H. Liang et al., Strain Effects on Flexible Perovskite Solar Cells, Advanced Science 10, 2304733 (2023) and F. Song et al., Mechanical Durability and Flexibility in Perovskite Photovoltaics: Advancements and Applications. Advanced Materials 36, 2312041 (2024)) none have studied its effects on the polymer substrates. Accordingly, mechanical reliability not just in the f-PSC layers itself but also in the substrate is desirable in determining the durability of f-PSCs.

### SUMMARY

The present disclosure is directed to a method and combination for mitigating or inhibiting the cracking of a substrate material, which may be compliant, that is contacting a layer material, which may be brittle. According to one aspect, the substrate material may be more compliant than the layer material. According to one aspect, the substrate material may be less brittle than the layer material. According to one aspect, the substrate material may have a Young's modulus lower than the layer material. According to one aspect, the layer material may have a Young's modulus greater than the substrate material. According to one aspect, cracking of the layer material directly contacting the substrate material and having a Young's modulus greater than the substrate material may undergo stress-induced cracking which may proceed through the layer material and into the substrate material contacting the layer material. Aspects of the present disclosure are directed to methods of determining cracking of such layer materials and substrate materials and layered combinations thereof.

According to one aspect, the present disclosure is directed to methods of preventing, mitigating, inhibiting, reducing or lowering cracking of the substrate material in a combination of layered materials, and to the combination of layered materials. The combination of layered materials may include two layers, three, layers, four layers, five layers, six layers, seven layers, eight layers, nine layers, ten layers or more. According to one aspect, the method includes providing an interlayer material between the layer material and the substrate material. According to one aspect, the method includes providing an interlayer material between the layer material and the substrate material to form a multilayer combination in series of the layer material, the interlayer material and the substrate material. According to one aspect, the interlayer material may have a Young's modulus lower than the layer material. According to one aspect, the interlayer material may have a Young's modulus lower than the layer material and may have a Young's modulus lower than the substrate material. According to one aspect, the interlayer material may directly contact the layer material. According to one aspect, the interlayer material may directly contact the substrate material. According to one aspect, the interlayer material may directly contact the layer material and may directly contact the substrate material. According to one aspect, the combination of the layer material and the substrate material with an interlayer material between the layer material and the substrate material, with the interlayer material having a Young's modulus lower than the layer material is characterized by a preventing, mitigating, inhibiting, reducing or lowering of the cracking of the substrate material when undergoing stress induced cracking of the layer material. According to one aspect, the combination of the layer material and the substrate material with an interlayer material between the layer material and the substrate material, with the interlayer material having a Young's modulus lower than the layer material and the substrate material is characterized by a preventing, mitigating, inhibiting, reducing or lowering of the cracking of the substrate material when undergoing stress induced cracking of the layer material. According to one aspect, the combination of the layer material and the substrate material with an interlayer between the layer material and the substrate material and directly contacting the layer material, with the interlayer material having a Young's modulus lower than the layer material and the substrate material is characterized by a preventing, mitigating, inhibiting, reducing or lowering of the cracking of the substrate material when undergoing stress induced cracking of the layer material. According to one aspect, the combination of the layer material and the substrate material with an interlayer between the layer material and the substrate material and directly contacting the layer material and the substrate material, with the interlayer material having a Young's modulus lower than the layer material and the substrate material is characterized by a preventing, mitigating, inhibiting, reducing or lowering of the cracking of the substrate material when undergoing stress induced cracking of the layer material. According to one aspect, the combination of the layer material and the substrate material with an interlayer between the layer material and the substrate material and directly contacting the layer material and the substrate material, with the layer material having a Young's modulus higher than the substrate material, and with the interlayer material having a Young's modulus lower than the layer material and the substrate material is characterized by a preventing, mitigating, inhibiting, reducing or lowering of the cracking of the substrate material when undergoing stress induced cracking of the layer material. It is to be understood that exemplary preventing, mitigating, inhibiting, reducing, resisting or lowering of the cracking of the substrate material in the layered combinations described herein including an interlayer material when undergoing stress induced cracking of the layer material is compared to a corresponding layered combination without the layer material present in the combination. Accordingly, one of skill will readily recognize that an aspect of the present disclosure is related to a layered combination including the interlayer as described herein even though no cracking of the layer material occurs or even though the layer combination is not subjected to stress which may result in cracking of the layer material. One of skill will readily recognize that the present disclosure is directed to the use of such a layered combination in exemplary embodiments such as perovskite solar cells that undergo stress, precisely because such a layered combination will advantageously resist cracking in the substrate layer, thereby prolonging the useful life of the exemplary embodiment, such as a perovskite solar cell. One of skill will readily broadly recognize that the present disclosure is directed to the use of layered materials having differing Young's modulus to provide a layered combination that resists cracking of the substrate material when cracking of the layer material occurs, such as a layered material contacting an interlayer material which contacts a substrate material, wherein the layer material has a Young's modulus greater than the substrate material, and wherein the interlayer material has a Young's modulus lower than the layer material, and also optionally lower than the substrate material. Such a combination has broad application in layered materials which undergo stress induced cracking. It is to be understood that the present disclosure has broad application to combinations of layer materials contacting one another in which it is desirable to prevent, mitigate, inhibit, reduce, resist or lower cracking of the substrate material, for example, when the layer material contacting the substrate material may undergo cracking.

The present disclosure is directed to perovskite solar cells and methods for preventing, mitigating, inhibiting, reducing, resisting or lowering cracking in a flexible perovskite solar cell, such as cracking in the substrate layer of a flexible perovskite solar cell, which may undergo cracking of the layer contacting the substrate layer. According to one aspect, the present disclosure is directed to improving the mechanical reliability of flexible devices on polymer substrates, including flexible perovskite solar cells (f-PSCs), by providing an interlayer as described herein between an electrode layer material and a substrate layer material. When an interlayer material as described herein is present between an electrode layer material and a substrate layer material, cracking of the electrode layer material may occur without cracking of the substrate layer material. In this manner, the mechanical durability of the device, such as a flexible perovskite solar cell is improved.

According to the present disclosure, methods are provided to determine pervasive, severe, and extensive cracking in high-toughness polymer substrates in bent f-PSCs, compromising their overall mechanical integrity. According to the present disclosure, substrate cracking is determined to be driven by the intensely amplified stress-intensity factor at the interface due to the elastic mismatch between a stiff film, such as an electrode layer material, contacting a compliant substrate, wherein the stiff film has a Young's modulus higher than the substrate. To mitigate such substrate cracking, an interlayer-engineering approach is provided herein. For example, a thin polymer interlayer with a stiffness less than the film and optionally less than the film and less than the substrate is introduced, such as between the film and the substrate, which diminishes the stress-intensity factor at the interface. This mitigation approach is generic, and can be applied to myriad flexible devices and multilayer systems that utilize stiff films on compliant substrates. A method is provided including introducing an interlayer of appropriate thickness such that it stops the substrate cracking or otherwise cracking of the substrate is absent. According to one aspect, the stiffness of this interlayer is between the stiffness of the substrate and the stiffness of the overlying thin film. According to one aspect, the stiffness of this interlayer must be between the stiffness of the substrate and the stiffness of the overlying thin film. There are myriad types of other flexible multilayer devices contemplated herein, such as batteries, displays, sensors, actuators, wearables, health-monitors, textiles, etc., that typically use stiff, brittle thin films on compliant, tough polymer substrates. Under stress (induced by bending, stretching, and/or twisting, during manufacturing and/or in-service) the polymer substrates included in these devices, which have not been subjected to methods described herein, crack via mechanisms discussed herein, thereby compromising the mechanical integrity of those devices. Methods described herein maintain the substrate integrity and hence improve the device life.

### BRIEF DESCRIPTION OF THE DRAWINGS

The patent or application file contains at least one drawing executed in color. Copies of this patent or patent application publication with color drawing(s) will be provided by the Office upon request and payment of the necessary fee. The foregoing and other features and advantages of the present embodiments will be more fully understood from the following detailed description of illustrative embodiments taken in conjunction with the accompanying drawings in which:

FIG. 1A-FIG. 1E: Bending of f-PSCs. FIG. 1A and FIG. 1B: Schematic illustrations (not to scale) of the bending test of f-PSC on ITO/PEN around a cylindrical mandrel of radius, r, (FIG. 1A) and the different layers in the f-PSCs (FIG. 1B). FIG. 1C and FIG. 1D: SEM images of f-PSCs bent to r=7 mm, in the bent state, showing top-surface view of ‘channel’ cracks (FIG. 1C), and FIB-cut cross-section of a ‘channel’ crack revealing cracking in all the f-PSCs layers and the PEN substrate (FIG. 1D). FIB-cutting was performed while in the bent state from a region similar to that indicated by the yellow rectangle in FIG. 1C). All FIB-cut specimens observed at 52° forward tilt angle, hence vertical micron bar is longer than the horizontal one, as indicated in FIG. 1D. (FIG. 1E) Relative PV parameters (V_{OC}, J_{SC}, FF, PCE) of f-PSC in the bent state as a function of r, under 1-sun AM 1.5G illumination at ambient conditions in reverse scan. Inset: schematic illustration (not to scale) of the PV performance measurement of f-PSCs in the bent state. Average and standard deviation of f-PSC measurements.

FIG. 2A-FIG. 2E: Bending of ITO/PEN. FIG. 2A: Top-view optical microscope image of an ITO/PEN bent to r=7 mm, in the bent state, showing ‘channel’ cracks in the ITO and no cracks in the bare PEN substrate (bottom region). FIG. 2B: SEM image of the two FIB-cuts. (FIB-cutting was performed while in the bent state from regions similar to those indicated by the yellow rectangles in (FIG. 2A).) FIG. 2C and FIG. 2D: Corresponding higher-magnification SEM images of each of the FIB-cuts showing, in cross-sections, cracking in both ITO and substrate cracking (FIG. 2C) and no cracking in the bare PEN substrate (FIG. 2D). FIG. 2E: Cross-sectional SEM image of a different FIB-cut showing deep cracking in the PEN substrate under ITO. All FIB-cut specimens observed at 52° forward tilt angle, hence vertical micron bars are longer than the horizontal ones, as indicated in FIG. 2B-FIG. 2E.

FIG. 3A-FIG. 3F: Modeling and mechanisms. FIG. 3A: Plot of K_{b}(c)/K(c) as function of c/h for different film/substrate combinations. Inset: schematic illustration (not to scale) of the crack of depth, c, in the film of thickness, h. FIG. 3B: Design map of the two Dundur's parameters, α and β, for film/substrate showing the boundary (α=−β) between substrate-cracking (α>−β) and crack-arrest regions (α<−β). The film/substrate combinations in FIG. 3A are indicated on the map in FIG. 3B. FIG. 3C-FIG. 3F: Schematic illustrations (not to scale) of cracking behavior under uniaxial tensile loading depicting no substrate cracking (FIG. 3C), ‘channel’ crack in film (FIG. 3D), extension of crack into the substrate (FIG. 3E), and substrate-cracking mitigation approach using an interlayer (FIG. 3F).

FIG. 4A-FIG. 4D: Mitigation of substrate-cracking. FIG. 4A to FIG. 4D: SEM images of FIB-cut cross-sections of ‘channel’ cracks in IZO/PEN (FIG. 4A), IZO/PMMA (250 nm)/PEN (FIG. 4B), IZO/PMMA (300 nm)/PEN (FIG. 4C), IZO/PMMA (600 nm)/PEN (FIG. 4D), bent to r=7 mm, in the bent state. A thin SiO₂ layer (˜20 nm) was used on top of PMMA. FIB cuts were made while in the bent state. All FIB-cut specimens observed at 52° forward tilt angle, hence vertical micron bars are longer than the horizontal ones, as indicated in FIG. 4A-FIG. 4D.

FIG. 5: Cyclic bending and electrical properties. The relative increase in the DC electrical resistance of IZO film on PEN substrate, where the substrate cracks in bending (r=7 mm; ε_{A}=0.0089), in the flat state as a function of bending cycles, n. Corresponding measurements of IZO on PMMA (300 nm)/PEN substrate, where the substrate does not crack in bending. Measurements from four different specimens for each material system reported. The solid lines connect the averages. The schematic illustration (not to scale) on the right depicts one bending cycle: flat→bent→flat.

FIG. 6A: Calculated applied uniaxial universal strain (SA), and the corresponding stress (GA) in each of the layers of the f-PSC, as if only that layer was on the substrate. ε_{A}=tₛ/2r and σ_{A}=Eε_{A}, where tₛ is the substrate thickness and E is the Young's modulus of the layer in question. The stress in the substrates (PEN, PET) is in the region close to the top. See Supplementary Text for stress/strain analyses of multiple layers on a substrate.

FIG. 6B: Calculated applied uniaxial universal strain (ε_{A}), and the corresponding stress (σ_{A}) in each of the layers in bilayer film/substrate bilayers. ε_{A}=tₛ/2r and Ω_{A}=Eε_{A}, where tₛ is the substrate thickness and E is the static Young's modulus of the layer in question from Table 1. The stress in the substrates (PEN, PET, PI) is in the region close to the top.

FIG. 7A-FIG. 7B: FIG. 7A: Relative DC electrical resistance change of the ITO at various bending radii, r, in the bent state, for only ITO on PEN, and with additional layers deposited on top of the ITO. Average and standard deviation of a number of specimens. Inset: schematic illustration (not to scale) of the ITO resistance measurement in the bent state. FIG. 7B: Corresponding density of ‘channel’ cracks for the stacks in FIG. 7A. Average and standard deviation of a number of specimens.

FIG. 8A-8C: Top-view optical microscope image of an ITO/PET bent to r=7 mm, in the bent state, showing ‘channel’ cracks in the ITO and no cracks in the bare PET substrate region at the bottom. FIG. 8B: SEM image of the FIB-cut cross-sections of ‘channel’ cracks in bent ITO/PET to r=7 mm (ε_{A}=0.0089) in the bent state, showing cracking of both ITO film and PET substrate. FIG. 8C: SEM images of FIB-cut cross-sections of ‘channel’ cracks in bent ITO/PI to r=5 mm (ε_{A}=0.0080) in the bent state, showing cracking of both ITO film and PI substrate. FIB-cutting was performed while in the bent state from the region similar to that indicated by the yellow rectangle in FIG. 8A. FIB-cut specimen observed at 52° forward tilt angle, hence vertical micron bar is longer than the horizontal one, as indicated in FIG. 8B.

FIG. 9A-FIG. 9B: Schematic illustration (not to scale) of shear-lag concept showing generation of concentrated shear stresses (ti) at the interface that promote substrate cracking (FIG. 9A), which are reversed in the case where low-modulus interlayer is introduced, leading to mitigation of substrate cracking (FIG. 9B).

FIG. 10: SEM image of FIB-cut cross-section of ‘channel’ crack in MHP/PEN bent to r=7 mm, in the bent state. FIB-cuts were made while in the bent state. The FIB-cut specimen was observed at 52° forward tilt angle, hence vertical micron bars are longer than the horizontal ones, as indicated.

FIG. 11: SEM image of a FIB-cut cross-section of ‘channel’ crack in IZO/PMMA (400 nm)/PEN, bent to r=7 mm, in the bent state. Thin Au layer (˜10 nm) was used on top of PMMA. FIB-cuts were made while in the bent state. The FIB-cut specimen was observed at 52° forward tilt angle, hence vertical micron bars are longer than the horizontal ones, as indicated.

FIG. 12A-FIG. 12C: FIG. 12A: Schematic illustration (not to scale) depicting a random cycle during the cyclic bending test: bent→flat→bent. FIG. 12B: Corresponding schematic illustrations (not to scale) of the hypotheses pertaining to IZO crack behavior affected by substrate cracking during cyclic bending of IZO/PEN with substrate cracking and improper closure, and IZO/PMMA (300 nm)/PEN (FIG. 12C) without substrate cracking.

### DETAILED DESCRIPTION

Aspects of the present disclosure are directed to a layered embodiment including a layer material, such as an electrode layer material, an interlayer material, such a polymer interlayer material, and a substrate material, wherein the interlayer material is between the layer material and the substrate material, and optionally, wherein the interlayer material directly contacts the layer material and the substrate material. It is to be understood that “directly contacting” may include the presence of a material that assists in combining or the processing of each layer to one another. According to one aspect, the layered embodiment may be part of a device where such a layered embodiment is desired, such as a flexible perovskite solar cell, wherein the layer material may be an electrode layer material and the substrate supports the flexible perovskite solar cell. The flexible perovskite solar cell includes additional layered materials as known in the art and as described herein.

### I. Layer Material

According to one aspect, a layer material as described herein has a Young's modulus higher than the substrate material. The layer material is provided as a layer in combination with a substrate material, also provided as a layer. It is to be understood that a layer material may also serve as a substrate material, so long as the layer material and the substrate material when in combination as layers are different and the layer material has a Young's modulus higher than the substrate material. Exemplary layer materials may be those known to one of skill in the art as electrodes or conductors. Exemplary layer materials are transparent conductors as are known in the art, and may be referred to as transparent conductors or transparent conductive oxides (TCO). Exemplary layer materials include those presented in the table below and the like as known in the art and with corresponding sheet resistance and thickness information when used as a transparent conductor. As described herein, the layer material may directly contact the substrate material or the layer material may directly contact the interlayer material. According to one aspect, the interlayer material may be between the layer material and the substrate material and may directly contact one or both of the layer material and substrate material.

| | A | B | C | |
|---|---|---|---|---|
| | Transparent | Sheet resistance | Thickness | D |
| 1 | conductors | (Ω/sq) | (nm) | References |
| 2 | SnO2:Sb | 32 | 220-230 | https://doi.org/10.1039/C5TC04117A |
| 3 | SnO2:F | 5.3 | 750 | https://doi.org/10.1016/j.jallcom.2009.08.130 |
| 4 | In₂O₃:Sn | 1.96 | 400-500 | https://doi.org/10.1007/s40195-014-0048-0 |
| 5 | Cd₂SnO₄ | 9.5-3.1 | 190-650 | https://doi.org/10.1109/PVSC.1997.654099 |
| 6 | ZnO:In | 16.2 | 200 | https://doi.org/10.1038/s41427-022-00411-6 |
| 7 | ZnO:Al | 16.5 | 373 | https://doi.org/10.1007/s10854-022-08015-0 |
| 8 | ZnO:B | 10 | 100 | https://doi.org/10.1039/C5TC04001A |
| 9 | ZnO:Ga | 5.5 | 825 | https://doi.org/10.1111/ [symbol] jag.16585 |
| 10 | ZnO:F | 7 | 650 | https://doi.org/10.1007/s10853-006-1255-5 |
| 11 | Ag nanowire-Zn₂SnO₄ | 7 | | https://doi.org/10.1039/D1RA00427A |
| 12 | ZTO-Ag-ZTO | 5.2 | 40-12-40 | https://doi.org/10.1021/acsami.0c10852 |
| 13 | F:ZnSnO₃ | 29 | | https://doi.org/10.1007/s10854-022-09600-z |
| [symbol] | [symbol] | [symbol] | [symbol] | [symbol] |

[symbol]

indicates data missing or illegible when filed

According to one aspect, the Young's modulus of the layer material, which may be a flexible film layer, is 2 times, 3 times, 4 times, 5 times, 6 times, 7 times, 8 times, 9 times, 10 times, 11 times, 12 times, 13 times, 14 times, 15 times, 16 times, 17 times, 18 times, 19 times, or 20 times greater than the Young's modulus of the flexible substrate. According to one aspect, the Young's modulus of the layer material, which may be a flexible film layer, is from 2 times to 20 times greater than the Young's modulus of the flexible substrate. According to one aspect, the Young's modulus of the layer material, which may be a flexible film layer, is from 3 times to 20 times greater than the Young's modulus of the flexible substrate. According to one aspect, the Young's modulus of the layer material, which may be a flexible film layer, is from 4 times to 20 times greater than the Young's modulus of the flexible substrate. According to one aspect, the Young's modulus of the layer material, which may be a flexible film layer, is from 5 times to 20 times greater than the Young's modulus of the flexible substrate. According to one aspect, the Young's modulus of the layer material, which may be a flexible film layer, is from 6 times to 20 times greater than the Young's modulus of the flexible substrate. According to one aspect, the Young's modulus of the layer material, which may be a flexible film layer, is from 7 times to 20 times greater than the Young's modulus of the flexible substrate. According to one aspect, the Young's modulus of the layer material, which may be a flexible film layer, is from 8 times to 20 times greater than the Young's modulus of the flexible substrate. According to one aspect, the Young's modulus of the layer material, which may be a flexible film layer, is from 9 times to 20 times greater than the Young's modulus of the flexible substrate. According to one aspect, the Young's modulus of the layer material, which may be a flexible film layer, is from 10 times to 20 times greater than the Young's modulus of the flexible substrate. According to one aspect, the Young's modulus of the layer material, which may be a flexible film layer, is from 11 times to 20 times greater than the Young's modulus of the flexible substrate. According to one aspect, the Young's modulus of the layer material, which may be a flexible film layer, is from 12 times to 20 times greater than the Young's modulus of the flexible substrate. According to one aspect, the Young's modulus of the layer material, which may be a flexible film layer, is from 13 times to 20 times greater than the Young's modulus of the flexible substrate. According to one aspect, the Young's modulus of the layer material, which may be a flexible film layer, is from 14 times to 20 times greater than the Young's modulus of the flexible substrate. According to one aspect, the Young's modulus of the layer material, which may be a flexible film layer, is from 15 times to 20 times greater than the Young's modulus of the flexible substrate. According to one aspect, the Young's modulus of the layer material, which may be a flexible film layer, is from 16 times to 20 times greater than the Young's modulus of the flexible substrate.

### II. Substrate or Interlayer Materials

According to one aspect, the interlayer material differs from the substrate material when used in the layered combination as described herein. The interlayer material and/or the substrate material may be flexible. According to one aspect, the interlayer material differs from the substrate material in at least the Young's modulus. According to one aspect, the interlayer material has a Young's modulus lower than the substrate material. Exemplary interlayer material or substrate materials may be thermoplastic polymers, elastomers, high-performance polymers, biopolymers, polymer5s for optical application, conductive or functionalized polymers, other polymers, metal foils or flexible glass materials. Exemplary thermoplastic polymers include polyimide (PI), polyethylene terephthalate (PET), polycarbonate (PC), polyethylene naphthalate (PEN), polypropylene (PP), polymethyl methacrylate (PMMA), polytetrafluoroethylene (PTFE), polyvinylidene fluoride (PVDF), fluorinated ethylene propylene (FEP), thermoplastic polyurethane (TPU), polydimethylsiloxane (PDMS), and the like. Exemplary elastomers include silicone rubber, styrene-ethylene-butylene-styrene (SEBS) and the like. Exemplary high-performance polymers include polyethersulfone (PES), polyetherimide (PEI), polybenzimidazole (PBI) and the like. Exemplary biopolymers include cellophane, polylactic acid (PLA), chitosan, chitosan-based polymers, polyethylene glycol and the like. Exemplary polymers for optical application include cyclic olefin copolymers (COC), polyvinyl alcohol (PVA) and the like. Exemplary conductive or functionalized polymers include poly(3,4-ethylenedioxythiophene) (PEDOT), polyaniline (PANI), polypyrrole (PPy) and the like. Exemplary other polymers include hydrogels, hydrogel-based polymers, photo-patternable polymers, self-healing polymers and the like. Exemplary metal foils include copper foil, aluminum foil, stainless steel foil, nickel foil, titanium foil, gold foil, silver foil, platinum foil, zinc foil, tantalum foil. molybdenum foil, tungsten foil, tin foil, lead foil, cobalt foil, beryllium foil, magnesium foil, chromium foil, iron foil, palladium foil, lithium foil, gallium foil, indium foil and the like. Exemplary flexible glass includes Corning Willow glass, Schott D 263 and the like.

According to one aspect, the Young's modulus of the substrate material, which may be a flexible substrate layer, is from 1.5 times to 10 times higher than the Young's modulus of the interlayer material, which may be a flexible interlayer. According to one aspect, the Young's modulus of the substrate material, which may be a flexible substrate layer, is from 2 times to 10 times greater than the Young's modulus of the interlayer material, which may be a flexible interlayer. According to one aspect, the Young's modulus of the substrate material, which may be a flexible substrate layer, is from 3 times to 10 times greater than the Young's modulus of the interlayer material, which may be a flexible interlayer.

### III. Substrate Cracking in Flexible Perovskite Solar Cell Layers

According to one aspect, the present disclosure utilizes methods to identify whether cracking in polymer substrates in bent flexible perovskite solar cells occurs. According to one aspect, an interlayer-engineering mitigation approach is described herein wherein an interlayer is included between a layer and a substrate as described herein which has application to myriad flexible devices and multilayer systems.

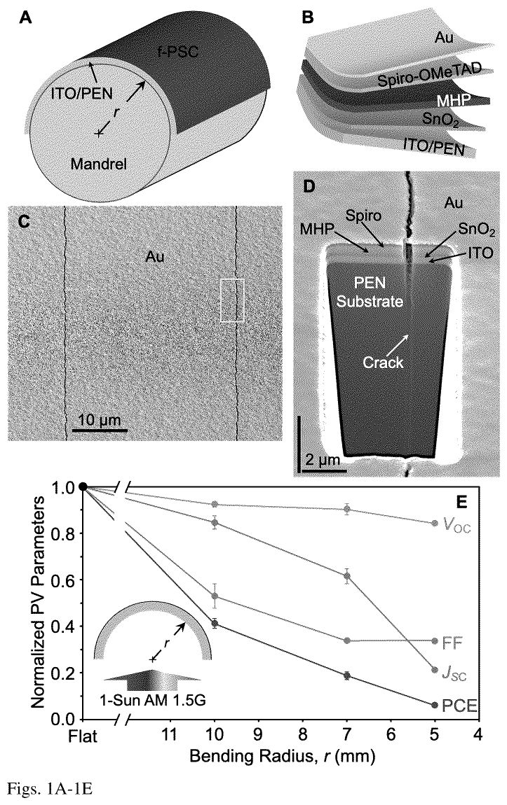

According to one aspect, a bending test is the most widely used protocol to evaluate the mechanical behavior of f-PSCs, as well as organic photovoltaics (OPVs). An exemplary bending test is described in K. Fukuda et al., A bending test protocol for characterizing the mechanical performance of flexible photovoltaics. Nature Energy 9, 1335-1343 (2024) hereby incorporated by reference in its entirety. This test, where a device is bent to a radius of curvature, r, around a cylindrical mandrel such that the entire cell is in uniaxial tension (see FIG. 1A), is also used to understand the failure mechanisms of flexible perovskite solar cells.

Exemplary substrates as described herein have extremely high toughness and thickness relative to the other brittle, thin layers in f-PSCs such as oxide layers and metal halide perovskite (MHP) layers. Aspects of the present disclosure are directed to the identification and measurement of pervasive, severe, and extensive cracking of the polymer substrates in bent f-PSCs observed in cross section. Aspects of the present disclosure are also directed to identifying general substrate-cracking mechanisms in f-PSCs, which are related to the elastic-properties mismatch between the film and the substrate. Exemplary modeling efforts pertaining to fracture mechanics of multilayer materials are disclosed in M. R. Gecit, Fracture of a surface layer bonded to a half space. International Journal of Engineering Science 17, 287-295 (1979); J. W. Hutchinson, Z. Suo, Mixed-mode Cracking in Layered Structures. Advances in Applied Mechanics 29, 63-191 (1991); J. L. Beuth, Cracking of Thin Bonded Films in Residual Tension. International Journal of Solids and Structures 28, 1657-1675 (1992); and M. D. Thouless, Z. Li, N. J. Douville, S. Takayama, Periodic cracking of films supported on compliant substrates. Journal of the Mechanics and Physics of Solids 59, 1927-1937 (2011), each of which are hereby incorporated by reference herein for their teachings of modelling of fracture mechanics. Aspects of the present disclosure are directed to the use of an interlayer between the conductor and the substrate which counters the elastic mismatch between conductor and substrate and inhibits cracking of the substrate when under stress.

### Example I

### Substrate Cracking Occurs When Directly Contacting a TCO

According to one aspect, the substrate of a multilayer device or upon which a multilayer device is placed or manufactured provides the foundation for the multilayer device. Accordingly, cracking of the substrate may compromise the overall mechanical integrity of the device. Also, substrate cracking makes the multilayer device highly susceptible to cyclic fatigue and other time-dependent failure modes such as creep and environment-assisted cracking/degradation. Accordingly, based on this understanding of the substrate-cracking mechanisms, it is desirable to develop an interlayer-engineering mitigation approach to counter or resist substrate cracking which can be applied to flexible devices and multilayer systems beyond flexible perovskite solar cells.

The n-i-p architecture of f-PSCs is depicted schematically in FIG. 1B, and they were fabricated on polyethylene naphthalate (PEN) polymer substrate (thickness tₛ˜125 μm), with an indium-tin oxide (ITO) transparent-conducting oxide (TCO) electrode coating. Here SnO₂ and Spiro-OMeTAD are used as the electron-transport layer (ETL) and the hole-transport layer (HTL), respectively, and Au is the top electrode. MHP is the metal halide perovskite layer.

Table 1 below lists the exemplary thicknesses and exemplary elastic properties of the different substrate and layer materials in f-PSCs.

TABLE 1

| | | | | | | | | Fracture | SEWF wₑ |
|---|---|---|---|---|---|---|---|---|---|
| | Thickness | | Young’s | Poisson’s | Young’ | \|Shear | Bulk | Toughness, | or |
| | (in this | | Modulus | Ratio | Modulus | Modulus | Modulus | K_{IC} | Toughness |
| Material | work) | | E* (GPa) | v | Ē^{‡} (GPa) | μ^{¶} (GPa) | k^{§} (GPa) | (MPa · m^{0.5}) | G_{C}^{†} (J · m⁻²) |
| PEN | ~125 | μm | 9 | 0.4 | 10.7 | 3.2 | 15.0 | — | 55,000 |
| ITO | 200-300 | | 137 | 0.25 | 146.1 | 54.8 | 91.3 | 0.8 | 5.3 |
| | nm | | | | | | | | |
| SnO₂ | ~30 | nm | 100 | 0.25 | 106.7 | 40.0 | 66.7 | — | — |
| MHP | ~500 | nm | 11 | 0.33 | 12.3 | 4.1 | 10.8 | 0.15 | 2.2 |
| Spiro | ~200 | nm | 0.5 | 0.45 | 0.6 | 0.2 | 1.7 | — | — |
| Au | ~70 | nm | 55 | 0.33 | 61.7 | 20.7 | 53.9 | 2 | 82 |
| PMMA | 200-600 | | 3 | 0.35 | 3.4 | 1.1 | 3.3 | 2.3 | — |
| | nm | | | | | | | | |
| IZO | ~250 | nm | 130 | 0.25 | 138.7 | 52.0 | 86.7 | | — |
| PET | ~125 | μm | 4 | 0.4 | 4.8 | 1.4 | 6.7 | — | 54,000 |
| PI | ~80 | μm | 4 | 0.34 | 4.5 | 1.5 | 4.2 | — | 48,900 |

*E (plane stress)
${}^{‡} \overline{E} = \frac{E}{( 1 - {v}^{2} )} ( plain srain )$ ${}^{¶} μ = \frac{E}{\{ 2 ( 1 + v ) \}} ( isotropic )$ ${}^{§} k = \frac{E}{\{ 3 ( 1 - 2 v ) \}} ( isotropic )$ ${}^{†} {G}_{C} = \frac{{K}_{IC}^{2} ( 1 - {v}^{2} )}{E} ( plain srain )$

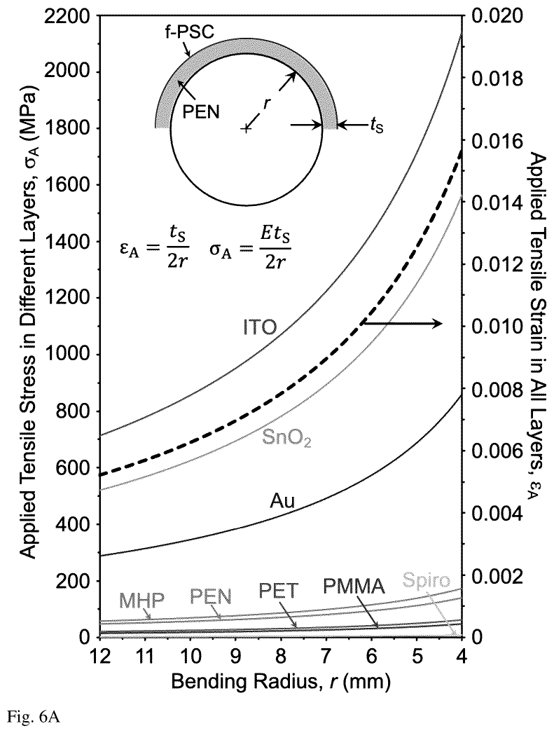

FIG. 1C is a top-view SEM image of such a f-PSC bent around a cylindrical mandrel of radius, r=7 mm, as shown in FIG. 1A. Typical ‘channel’ cracks on the Au top-electrode surface (parallel to the bending axis) are visible in FIG. 1C. Since all the underlying functional layers in f-PSC and the ITO are brittle and/or relatively very thin (20 to 500 nm), all of them are also expected to crack under the externally applied bending uniaxial tensile strain, ε_{A}=tₛ/2r estimated at 0.0089 for r=7 mm. FIG. 6A plots the applied uniaxial tensile universal strain (ε_{A}), and the corresponding stress (σ_{A}) in each of the f-PSC layers, as a function of r. Note that any tensile or compressive internal residual stresses in the layers, would augment or diminish, respectively, the total stresses in the layers in the bent state. In contrast, prior to the present disclosure, the PEN substrate is not expected to crack because it is much thicker and extremely tough, i.e. resistant to fracture (see Table 1 above), with a specific effective work of fracture or SEWF (wₑ) of ˜55,000 J·m⁻². See A. Arkhireyeva et al., Fracture Behavior of polyethylene Naphthalate (PEN). Polymers 43, 289-300 (2002). By comparison, the equivalent toughness, Gc, of ITO is ˜5 J·m⁻², and that of MHP is ˜2 J·m⁻². See Z. Dai et al., The Mechanical Behavior of Metal-Halide Perovskites: Elasticity, Plasticity, Fracture, and Creep. Scripta Materialia 223, 115064 (2023). However, when SEM observations are performed on cross-sections created by focused ion beam (FIB), deep cracks are observed in the PEN substrate (see FIG. 1D). This is in addition to the expected cracking of all the other f-PSC layers. Note that none of the horizontal interfaces appear to delaminate. Both FIB-cutting of cross-sections and SEM imaging of the specimens were performed in the bent state; cracks in post-bending flat specimens are often not visible in the SEM.

The PV performance parameters of the f-PSCs were measured in the bent state at different r, and are plotted in FIG. 1E. While the open circuit voltage (V_{OC}) reduction with decreasing r is relatively small, the short-circuit current density (J_{SC}) and fill factor (FF) decrease at a much faster rate. The latter two parameters contribute to the significant decrease in the power conversion efficiency (PCE) of the f-PSCs, retaining only ˜6% of the initial PCE at r=5 mm.

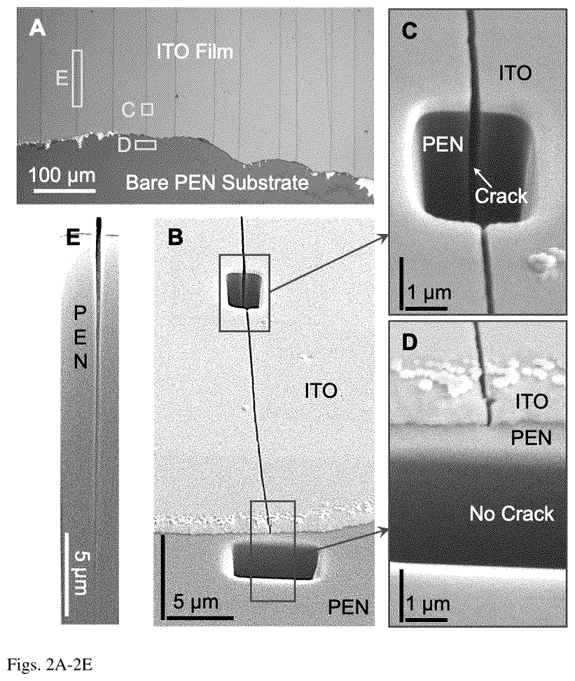

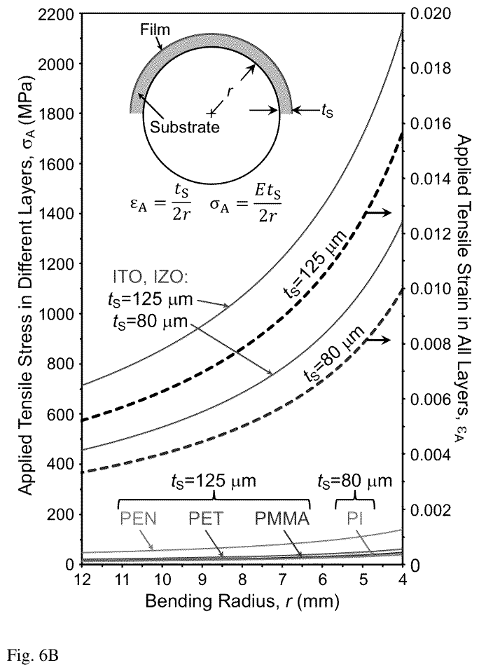

FIG. 7A plots the relative change in the resistance (ΔR/R_{O}) of the ITO in the bent state during bending at different r, where the resistance R (in dark) is measured in the direction perpendicular to the bending axis (FIG. 7A inset), R_{O} is the initial resistance in the flat state, and ΔR=R−R_{O}. For just the ITO on PEN substrate, beyond a critical bending radius (r=10 mm), ITO ΔR/R_{O} increases rapidly with decreasing r. A similar trend is observed for ITO ΔR/R_{O} with SnO₂ ETL on top. The ITO ΔR/R_{O} increase is somewhat moderated with further deposition of the MHP layer and of the full f-PSC stack. FIG. 7B plots the experimentally measured density of ‘channel’ cracks as a function of decreasing r, where a monotonic increase is observed. FIG. 2A shows an example of ‘channel’ cracks array in ITO that was used to measure the crack density. Thus, the significant decrease in PCE as a function of decreasing r seen in FIG. 1E is attributed to the increase in the series resistance of the f-PSC in the bent state due to the increasing crack density in the ITO electrode.

Since substrate-cracking behavior observed in FIG. 1D has profound implications on the durability and reliability of f-PSCs, further investigations were carried out to understand the genesis of such substrate cracking. Based on modeling, the very high Young's modulus, E, (stiffness) of the ITO (E˜137 GPa) relative to the compliant PEN (E˜9 GPa) is believed to be responsible for the substrate cracking in f-PSCs. As described herein, the layer material as described herein has a higher Young's modulus than the substrate material as described herein, such that cracking of the substrate material occurs when subjected to stress on both the layer material and the substrate material.

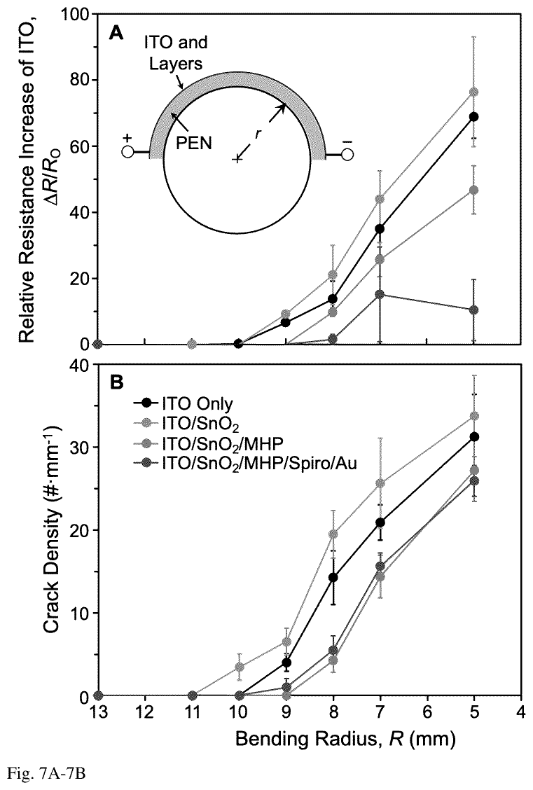

The cracking behavior of an indium tin oxide (ITO) layer directly contacting a polyethylene naphthalate (PEN) substrate layer (ITO/PEN) under bending was studied. FIG. 2A is a top-view optical micrograph of ITO/PEN in the bent state (r=7 mm), where typical array of ‘channel’ cracks, parallel to the bending axis, is observed. However, ‘channel’ cracks do not extend into bare PEN substrate part without the ITO (bottom region of the micrograph). Such observations have been reported in the literature on numerous occasions, and it is generally assumed that the tough polymer substrate under the brittle TCO does not crack. See H. S. Jung et al., Experimental and numerical investigation of flexibility of ITO electrode for application in flexible electronic devices. Microsystems Technology 23, 1961-1970 (2017) and Y. Leterrier et al., Mechanical integrity of transparent conductive oxide films for flexible polymer-based displays. Thin Solid Films 460, 156-166 (2004). However, surprisingly, when FIB-cut cross-sections are observed in the SEM, where both FIB-cutting and SEM observations are performed in the bent state, FIGS. 2B and 2C clearly show that PEN under the ITO cracks, and that the ‘channel’ cracks penetrate deep into the PEN substrate underneath. FIGS. 2B and 2D confirm that the bare PEN substrate is uncracked. To further investigate the depth of the cracks in the PEN, a longer ‘trench’ along the crack was FIB-cut, revealing >25-μm deep cracks (FIG. 2E), which is ˜20% of the total substrate thickness. This type of pervasive, severe, and extensive substrate cracking was observed in many ‘channel’ cracks within the same ITO/PEN specimen, and also in different ITO/PEN specimens. Furthermore, similar behavior is observed in ITO on a different polymer substrate, viz polyethylene terephthalate (PET), in FIG. 8.

A few studies reporting cracking in compliant, tough polymer substrates, such as polydimethylsiloxane (PDMS) and PET, underneath either stiff, ductile metal films (Au/PDMS, (see N. J. Douville et al., Fracture of metal coated elastomers. Soft Matter 7, 6493-6500 (2011)), Al/PDMS (see S. I. Badrudin et al., Eliminating surface cracks in metal film-polymer substrate for reliable flexible piezoelectric devices. Engineering Science and Technology, an International Journal 50, 101617 (2024)) or stiff, brittle ceramic films (SiNₓ/PET, see K. Kim et al., Influence of Polymer Substrate Damage on the Time Dependent Cracking of SiNx Barrier Films. Scientific Reports 8, 4560 (2018)). Cracking has also been reported in compliant, tough brass substrate underneath stiff, brittle TiN film. See T. Gao et al., Brittle film-induced cracking of ductile substrates. Acta Materialia 99, 273-280 (2015). However, in all those cases the substrate-cracking is modest, and does not evidence substrate cracking in TCO/polymer systems pertinent to flexible devices, including PSCs. Thus, the pervasive, severe, and extensive substrate-cracking described herein was unexpected.

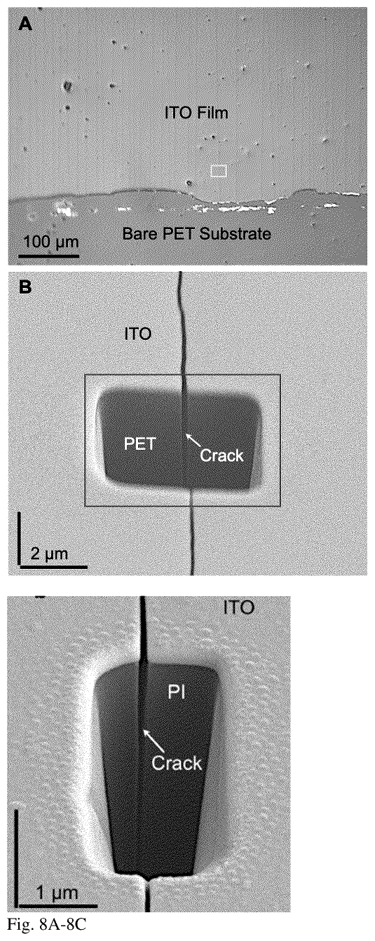

The problem of cracking of compliant substrates underneath stiff films has been modeled in some past studies. The elegant analytical model by Gecit (see M. R. Gecit, Fracture of a surface layer bonded to a half space. International Journal of Engineering Science 17, 287-295 (1979)) has shown that when a putative crack of depth, c, in a stiff film of thickness, h, (Al or steel) under uniaxial tension approaches the interface with a compliant substrate (epoxy or Al), the crack-driving stress-intensity factor, K_{b}(c), increases dramatically relative to reference K(c) for no elastic mismatch between the film and the substrate. This is the result of concentrated shear stresses induced in the substrate at the crack-interface intersection due to the elastic mismatch, (see J. L. Beuth et al., Cracking of Thin Films Bonded to Elastic-Plastic Substrates. Journal of the Mechanics and Physics of Solids 44, 1411-1428 (1996)) as depicted schematically in FIG. 9. By corollary, when the elastic mismatch is reversed, i.e. compliant film (Al) on stiff substrate (steel), K_{b}(c)/K(c) diminishes.

According to the present disclosure, the elastic mismatch between the film (F) and the substrate(S) is defined in terms of the Dundur's parameters, α and β, which incorporate not only their respective Young's moduli (E_{F}, E_{S}) but also bulk moduli (μ_{F}, μ_{S}) and Poisson's ratios (v_{F}, vₛ), and are listed in Table 2, Mechanical properties (static) from Table 1 and Dundur's parameters (α and β) for several different film (F)/substrate(S) combinations: (see J. W. Hutchinson et al., Mixed-mode Cracking in Layered Structures. Advances in Applied Mechanics 29, 63-191 (1991))

$$α = \frac{\overline{{E}_{F}} - \overline{{E}_{S}}}{\overline{{E}_{F}} + \overline{{E}_{S}}} and \qquad ( 1 )$$

$$β = \frac{1}{2} \frac{{μ}_{F} ( 1 - 2 {v}_{S} ) - {μ}_{S} ( 1 - 2 {v}_{F} )}{{μ}_{F} ( 1 - {v}_{S} ) + {μ}_{S} ( 1 - {v}_{F} )} , \qquad ( 2 )$$

where Ē=E/(1−v²) is the plane strain Young's modulus.

TABLE 2

| Film/ | Ē_{F} | Ēs | | | μ_{F} | μ_{S} | α* | β^{#} |
|---|---|---|---|---|---|---|---|---|
| Substrate | (GPa) | (GPa) | v_{F} | v_{S} | (GPa) | (GPa) | (17) | (17) |
| ITO/PEN | 146.1 | 10.7 | 0.25 | 0.4 | 54.8 | 3.2 | 0.86 | 0.13 |
| IZO/PEN | 138.7 | 10.7 | 0.25 | 0.4 | 52.0 | 3.2 | 0.86 | 0.13 |
| ITO/PET | 146.1 | 4.8 | 0.25 | 0.4 | 54.8 | 1.4 | 0.94 | 0.15 |
| IZO/PET | 138.7 | 4.8 | 0.25 | 0.4 | 52.0 | 1.4 | 0.93 | 0.15 |
| ITO/PMMA | 146.1 | 3.4 | 0.25 | 0.35 | 54.8 | 1.1 | 0.95 | 0.22 |
| IZO/PMMA | 138.7 | 3.4 | 0.25 | 0.35 | 52.0 | 1.1 | 0.95 | 0.22 |
| ITO/PI | 146.1 | 4.5 | 0.25 | 0.34 | 54.8 | 1.5 | 0.94 | 0.23 |
| IZO/PI | 138.7 | 4.5 | 0.25 | 0.34 | 52.0 | 1.5 | 0.94 | 0.22 |
| PMMA/PEN | 3.4 | 10.7 | 0.35 | 0.4 | 1.1 | 3.2 | −0.52 | −0.13 |
| PMMA/PET | 3.4 | 4.8 | 0.35 | 0.4 | 1.1 | 1.4 | −0.16 | −0.06 |
| PMMA/PI | 3.4 | 4.5 | 0.35 | 0.34 | 1.1 | 1.5 | −0.14 | −0.03 |

${}^{*} α = \frac{\overline{{E}_{F}} - \overline{{E}_{S}}}{\overline{{E}_{F}} + \overline{{E}_{S}}}$ ${}^{\#} β = \frac{1}{2} \frac{{μ}_{F} ( 1 - 2 {v}_{S} ) - {μ}_{S} ( 1 - 2 {v}_{F} )}{{μ}_{F} ( 1 - {v}_{S} ) + {μ}_{S} ( 1 - {v}_{F} )}$

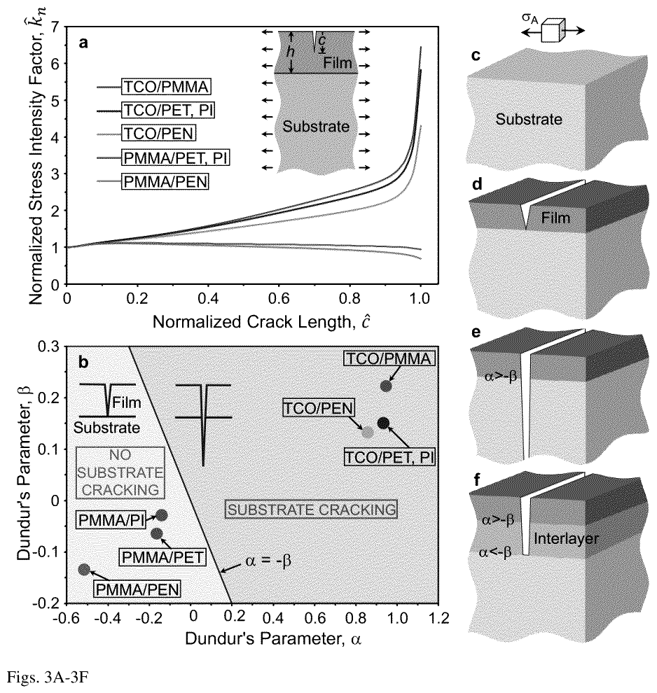

Using the Gecit model, K_{b}(c)/K(c) is calculated for putative Mode I tensile cracks in ITO/PEN and ITO/PET film/substrate combinations in FIG. 3A, whose Dundur's parameters are listed in Table 2 and plotted in FIG. 3B. As shown in FIG. 3A, for both cases, K_{b}(c)/K(c) rises rapidly with the normalized crack depth, c/h, and asymptotically approaches infinity as the crack approaches the interface. Thus, an incipient crack (small c/h) at the surface of the film loaded in uniaxial tension (as in the bending test) will propagate provided the K_{b}(c)>K_{IC} condition is satisfied, where K_{IC} is the fracture toughness of the film. In such a loading situation, K(c)∝c^{0.5}, and, thus, the crack is expected to propagate unstably. The results in FIG. 3A show that the presence of the compliant substrate accelerates the rise of K_{b}(c) for a crack in the film dramatically, over and beyond the conventional c^{0.5}-scaling increase represented by K_{b}(c)/K(c)=1. The singularity at the interface implies that the crack will continue to propagate into the substrate regardless of the toughness of the substrate; by corollary, in the absence of the film, the substrate would otherwise not crack. FIGS. 3C-3E depict schematically this substrate-cracking behavior. Once the crack enters into the substrate, the K_{b}(c)/K(c) is expected to decrease as the crack propagates deeper into the substrate, an effect modeled by Thouless, et al. See M. D. Thouless et al., Periodic cracking of films supported on compliant substrates. Journal of the Mechanics and Physics of Solids 59, 1927-1937 (2011). Also, in the case of bending, the applied uniaxial tensile stress experienced by the crack tip decreases as it propagates deeper into the substrate, and the stress goes to zero at the ‘neutral axis,’ before becoming compressive. See K. Fukuda et al., A bending test protocol for characterizing the mechanical performance of flexible photovoltaics. Nature Energy 9, 1335-1343 (2024). This explains why the substrate cracks in ITO/PEN and ITO/PET, although deep, are limited to ˜20% of the substrate thickness.

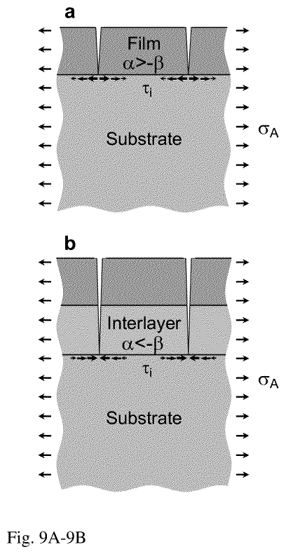

Using the Gecit model, a design map in FIG. 3B was constructed, where K_{b}(c)/K(c) is expected to increase dramatically as the crack approaches the interface (c/h→1) for α>−β, resulting in substrate cracking. By corollary, K_{b}(c)/K(c) will decrease with c/h→1 for α<−β, resulting in crack arrest at the interface. ITO/PEN and ITO/PET combinations lie in the substrate-cracking region on the map in FIG. 3B. Indium-zinc oxide (IZO) is another exemplary TCO for flexible electronics, and its elastic properties are very similar to those of ITO. Since the much stiffer ITO (or IZO) film is key to the substrate-cracking problem, one can envision replacing the TCO with alternate, less stiff transparent-conducting electrodes made of polymers, metal meshes, or carbon-based nanomaterials, although they are typically inferior to TCO. See Y. Xu et al., Recent Progress of Electrode Materials for Flexible Perovskite Solar Cells. Nano-Micro Letters 14, 117 (2024). However, the design map in FIG. 3B indicates that even a modest elastic mismatch between MHP film (E_{F}˜11 GPa) on PEN substrate (E_{S}˜9 GPa), without the ITO should result in substrate cracking. This is confirmed in bending experiments on MHP/PEN specimens (FIG. 10), where substrate cracking is observed, although it is moderate (crack depth ˜2 μm). Thus, elimination of the TCO may not be a viable substrate-cracking mitigation approach, leading to the development of the interlayer approach described herein.

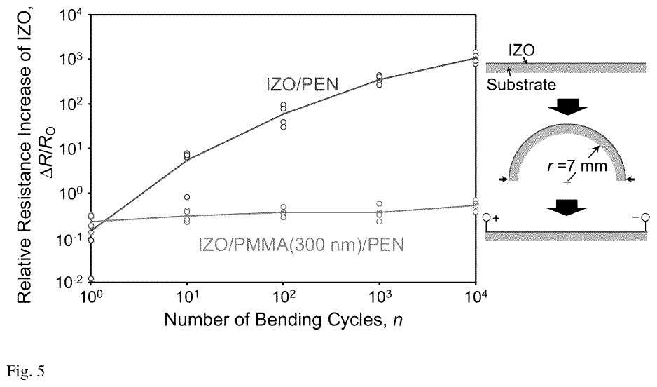

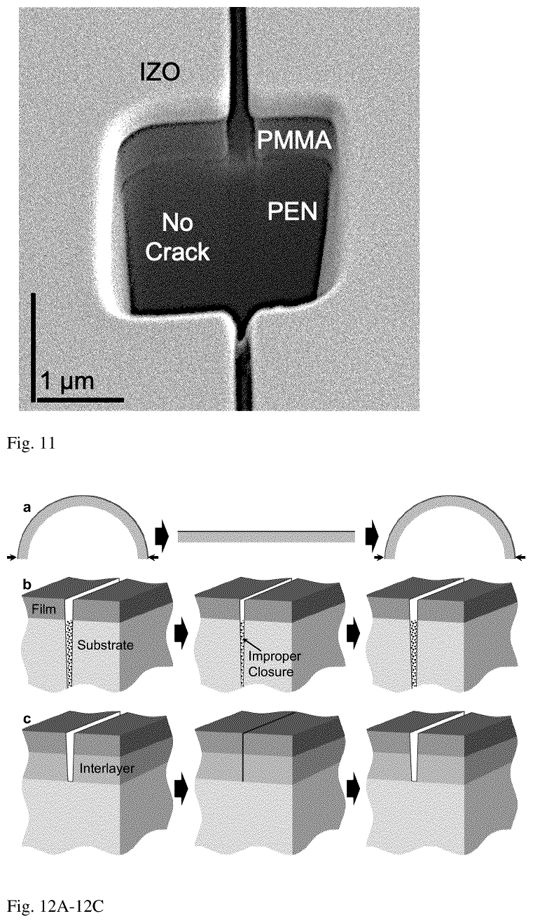

In light of substrate-cracking, it is hypothesized that when the TCO/polymer sheet is subjected to cyclic bending (i.e. multiple cycles), the propensity for the substrate cracks to close properly when returned to the flat state will decrease progressively. This is most likely due to the accumulation of debris within the substrate cracks, their propagation deeper into the substrate, and growing misalignment of the mating crack walls, with increasing number of cycles. This, in turn, is likely to progressively prevent the TCO crack walls from making good contact, thereby resulting in increasing ΔR/R_{O} (flat state) with number of cycles, n. It is also hypothesized that in the case where substrate cracking is eliminated, e.g. in IZO/PMMA (300 nm)/PEN, the flat-state ΔR/R_{O} may not increase with increasing n. These hypotheses are illustrated schematically in FIGS. 12A-12C. To verify these hypotheses, ΔR/R_{O} of IZO/PEN sheets was measured in the flat state (FIG. 5) after subjecting them to bending cycles in the range n=1 to 10⁴, at bending radius r=7 mm (ε_{A}=0.0089). FIG. 5 plots these data, which clearly show progressive increase in flat-state ΔR/R_{O} with number of bending cycles, n, which reaches up to ˜1,200 after 10⁴ bending cycles. In contrast, no appreciable change in ΔR/R_{O} could be measured in IZO/PMMA (300 nm)/PEN in the flat state, even after 10⁴ cycles where ΔR/R_{O}˜0.5. These results reinforce the critical importance of substrate cracking in the degradation of TCO electrical properties. Since electrical continuity of the TCO film is key to the proper functioning of any multilayer device built upon TCO/polymer sheets, substrate cracking is highly detrimental for the durability and reliability of such devices.

### Example II

### Use of an Interlayer Inhibits Crack Formation in Substrates

According to the present disclosure, an interlayer approach is provided for mitigating the substrate-cracking problem in TCO/polymer system, without having to resort to TCO elimination. According to the present disclosure, an exemplary transparent, compliant interlayer between the TCO and polymer substrate, with an E that is lower than those of both the TCO and the substrate is provided. As an example, polymethyl methacrylate (PMMA) interlayer of E_{IL}˜3 GPa is provided between the PEN substrate (E_{S}˜9 GPa) and the IZO (E_{F}˜130 GPa (33)) (Table 1). The interlayer has a Young's modulus lower than the layer material (IZO) and the substrate layer material (PEN). FIG. 3A plots K_{b}(c)/K(c) for the combinations IZO/PMMA and PMMA/PEN, whose Dundur's parameters are listed in Table 2 and plotted in FIG. 3B. For the IZO/PMMA case, a very rapid rise in K_{b}(c)/K(c) is observed as the crack approaches the interface, commensurate with the higher a for that combination. Thus, a putative crack in IZO film is expected to propagate into the PMMA interlayer underneath, which is reflected in the design map in FIG. 3B. However, in the case of PMMA/PEN combination, for a putative crack in the PMMA layer, the K_{b}(c)/K(c) diminishes as the crack approaches the interface. Therefore, the crack is expected to be arrested, precluding any substrate cracking, which is consistent with the design map in FIG. 3B for the PMMA/PEN combination. This hypothesis is depicted schematically in FIG. 3F.

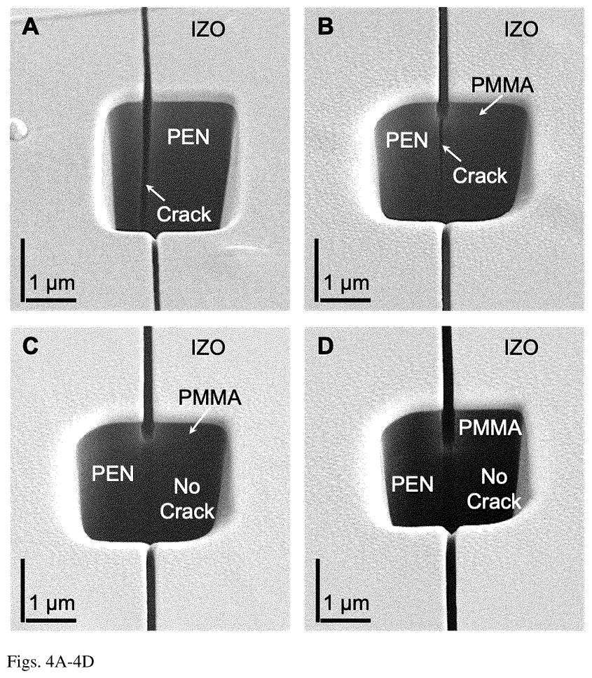

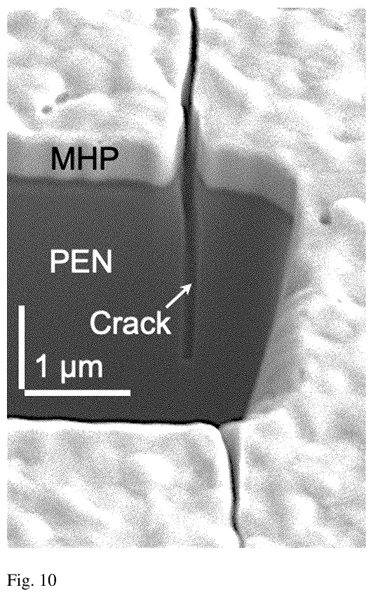

To test this hypothesis experimentally, PMMA layers of different thicknesses (˜250, ˜300, ˜600 nm) were spin-coated onto PEN substrates. However, PMMA is unable to withstand the sputtering conditions during the subsequent IZO deposition. Therefore, a thin, transparent layer of SiO₂ (˜20 mm) is thermally-evaporated on the PMMA surface to protect it. Considering the thinness of the SiO₂, it is not expected to interfere with this mitigation approach. IZO (˜250 nm thickness), which has an E similar to that of ITO (Table 1), was then sputter-deposited on top of the SiO₂. As described herein, even though the PMMA interlayer has a thin coating of SiO₂ in order to provide adherence of the IZO layer, one of skill will understand that the PMMA layer contacts the IZO layer. At least, one of skill will recognize the presence of a protective layer between the IZO layer and the PMMA interlayer, if need be. Where no PMMA interlayer is present, substrate-cracking is observed in the FIB-cut cross-section in FIG. 4A, which is similar to that in the ITO/PEN case (FIG. 2B-FIG. 2C). Similarly, in the case of 250-nm PMMA interlayer, PEN cracking is observed in FIG. 4B. However, dramatic arrest of ‘channel’ cracks at the PMMA/PEN interface is observed in FIG. 4C with a ˜300 nm PMMA interlayer. Similar behavior is observed in FIG. 4D with a thicker PMMA interlayer (˜600 nm). In related experiments, instead of the SiO₂ protective layer, Au layer (˜10 nm) was deposited, which allowed better contrast delineation of the PMMA layer in the SEM; same type of crack-arrest behavior is observed with a ˜400 nm PMMA interlayer (FIG. 11). This indicates that a relatively thin layer of PMMA (300-400 nm) is sufficient for suppressing substrate cracking under these conditions. Thus, this approach can be readily adopted for all f-PSCs, and also OPVs, that use polymer substrates with TCO electrodes.

Besides flexible PV devices, there are many types of other flexible multilayer devices, such as batteries, displays, sensors, actuators, wearables, health-monitors, textiles, etc., that typically use stiff, brittle films on compliant, tough polymer substrates. Under tension (induced by bending, stretching, and/or twisting, during manufacturing and/or in-service) the polymer substrates are expected to crack via the mechanisms discussed above, thereby compromising the overall mechanical integrity of those devices. While the severity and extent of substrate cracking will depend on the elastic mismatch, relative thicknesses, and applied tensile stresses, the general mitigation approach of introducing an interlayer of a material of appropriate thickness, such that E_{IL}<E_{S}<E_{F} as described herein with respect to a flexible perovskite solar cell is potentially applicable to those myriad multilayer devices.

### Example III

### Materials

All materials and reagents were used as-received commercially without further purification, which include: lead (II) iodide (PbI₂; 99%, Sigma Aldrich, USA), formamidinium iodide (FAI; >99.99%, Greatcell Solar Materials, Australia), lead (II) bromide (PbBr₂; Materials, Australia), cesium iodide (CsI; 99.999%, Sigma Aldrich, USA), methylammonium bromide (MABr; >99.99%, Greatcell Solar Materials, Australia), methylammonium chloride (MACI; >99.99%, Greatcell Solar Materials, Australia), N,N-dimethylformamide (DMF; 99.8%, anhydrous, Sigma Aldrich, USA), dimethyl sulfoxide (DMSO; ≥99.9%, anhydrous, Sigma Aldrich, USA), ethanol (>99.5%; Sigma Aldrich, USA), acetone (>99.5%, VWR, USA), SnO₂ colloidal dispersion (SnO₂-CD; 15 wt % in H₂O, Alfa Aesar, USA), isopropanol (IPA; 99.5%, anhydrous, Sigma Aldrich, USA), bis(trifluoromethane) sulfonimide lithium salt (Li-TFSI; 99.95%, Sigma Aldrich, USA), 4-tert-butylpyridine (tBP; 98%, Sigma Aldrich, USA), acetonitrile (AcN; 99.8%, anhydrous, Sigma Aldrich, USA), chlorobenzene (CB; 99.8%, anhydrous, Sigma Aldrich, USA), spiro-OMeTAD (>99.8%, Lumtec, Taiwan), poly(methyl methacrylate) solution (PMMA; Sigma Aldrich (182265), USA), polyethylene naphthalate sheets substrates (PEN; Goodfellow Corp., USA), polyimide sheets (PI; Kapton, Kolon Industried, S. Korea), indium-tin-oxide-coated polyethylene terephthalate substrates (ITO/PET; Sigma Aldrich (639303), USA), and ITO-coated PEN substrates (ITO/PEN; Peccell, Japan).

### Example IV

### Flexible Devices (PSCs) Fabrication

The ITO (300 nm)/PEN (125 μm) substrates were patterned using the Zn—HCl chemical-etching method. This was done to avoid edge effects of ITO flaws caused while cutting the ITO-coated PEN substrates. The substrates were then sonicated in a solution of IPA, acetone, and DI (1:1:1 v/v) for 20 min. The substrates were then dried under flowing dry N₂ and attached to an appropriately-sized microscope glass slide using Kapton tape. The substrates were treated under ultraviolet ozone (UVO) for 30-35 min and transferred to a controlled-humidity (<10% RH) glovebox. Immediately after this, an SnO₂ solution (SnO₂-CD in DI water; 1:3 v/v, filtered with a 0.22 mm PTFE filter) was spin-coated at 4,000 rpm with a ramp of 1,000 rpm s⁻¹ for 30 s, followed by drying at 120° C. for 20 min or 60 min on a hotplate.

The metal-halide perovskite (MHP) precursor solution (1.61 M) was prepared by dissolving 742.2 mg of PbI₂, 224.4 mg of FAI, 16.2 mg of MABr, 20.3 mg of MACI, and 19.8 mg of CsI in a mixture of 800 μL DMF and 200 μL DMSO. This is to result in thin films of final nominal composition of Cs_{0.05}MA_{0.13}FA_{0.82}Pb(I_{2.9}Br_{0.01}). This precursor solution was stirred for 2 h at room temperature and filtered prior to use. After treating the substrates under UVO for 15 min, the MHP layer was spin-coated on the prepared substrate at 1,000 rpm, with a ramp of 200 rpm·s⁻¹ for 10 s followed by 5,000 rpm, with a ramp of 1,000 rpm's⁻¹, for 30 s. Anhydrous CD (0.2 mL) was dripped in a single stream onto the rotating substrate 15 s before the end. Subsequently, the film was annealed for 30-40 min at 100° C. under ˜17% RH on a hotplate. The humidity was then reduced to <10% RH. The Spiro-OMeTAD layer was then spin-coated at 4,000 rpm, with a ramp of 2,000 rpm's⁻¹, for 20 s using a solution of 90 mg Spiro-OMeTAD, 39.5 μL of tBP, 23 μL of Li-TFSI (520 mg dissolved in 1 mL of acetonitrile) in 1 mL CB (filtered with 0.22 μm PTFE filter). All processing was performed in a humidity-controlled ambient-air glovebox. Finally, 70-nm thick Au electrode was deposited by thermal evaporation. The flexible perovskite solar cells (f-PSCs) were then detached from the glass slide.

The individual layers, in specimens that are not full f-PSC devices but were used for characterization and testing, were deposited using the above procedures.

### Example V

### PV Performance Measurement

The PV performance of the f-PSCs was performed in the bent state. For this, a stainless-steel vise was partially covered with Kapton tape to avoid shorting. Thin rectangular pieces of glass were the attached to the back of the f-PSC to hold the device between the jaws of the vise. Individual copper tapes (3M, USA) were carefully attached to each cell (0.3 cm² active area) of the f-PSC without damaging the gold electrodes. The distance between vise jaws was adjusted such the f-PSC just fit in the opening. A multimeter was used to make sure none of the cells were accidentally shorted. A current density (J)-voltage (V) responses of f-PSCs were recorded in this initial flat state. The jaws were then slowly moved towards each other such that the bending radii (r) of the entire active part of the devices were 10, 7, or 5 mm, and the distance between the light source and the f-PSC setup was adjusted accordingly to account for the curvature. The J-V responses of the f-PSCs in the bent state were recorded, where a number of different f-PSCs were tested per r condition. The J-V responses were measured using a 2400 source meter (Keithley, USA) under simulated 1-sun illumination (AM 1.5G, 100 mW·cm⁻²), which was generated using a class AAA simulator (Oriel Sol3A, Newport, USA) in air (˜25° C., ˜25% RH). The light intensity was calibrated using a standard Si photodiode. Typically, the f-PSCs were measured in reverse scan (from V_{OC} to J_{SC}) and forward scan (from J_{SC} to V_{OC}) with a step size of 0.02 V and a delay time of 10 ms. All f-PSCs were measured after light soaking for 30 s.

A multimeter (179, Fluke, USA) was used to measure the DC electrical resistance of the ITO/PEN while in the bent state. Stacks of various thin films were fabricated on top of the ITO leaving two opposite ends exposed. Square cuts were made on all 4 edges so that the exposed ITO did not bend on the mandrel. Copper tape was attached to these exposed ITO on both ends, and the initial resistance (R_{O}) was carefully measured, which was found to be very close to a value calculated from its specified sheet resistance of the ITO (13-15Ω/•). The ITO/PEN specimens were then manually bent on the cylindrical mandrels of different r (10, 7, or 5 mm) such that the stack of films were bent on the mandrel, but the exposed ITO parts were tangential to the mandrel. Copper tapes were attached to the multimeter to measure the resistance of the ITO in the bent state. In each r condition, a minimum of three specimens (about four specimens) were used for this measurement. All bending and measurement procedures were performed in a dark, dry-air glovebox (<5% RH).

Cyclic bending tests were performed on IZO/PEN and IZO/PMMA (300 nm)/PEN sheets in air (˜25° C., ˜25% RH) using an automatic cyclic mechanical tester (PR-BDM-100, Puri, China), where the acrylic cylindrical mandrel was of radius r=7 mm; each bending cycle is: flat→bent→flat.⁴³ Testing was performed for 10,000 cycles, at the rate of ˜1 cycle×s⁻¹. Testing was interrupted periodically, and the DC electrical resistance of the IZO films in the flat state were measured using the method described above. The initial resistance (R_{O}) values of the IZO films in the flat state were measured before the commencement of cyclic bending tests.

### Example VI

### Deposition of PMMA Thin Films

A solution of PMMA in CB (5 wt %, heated at 70° C. overnight) was spin-coated on PEN substrates under ambient conditions at 6,000, 4,000, 2000 or 1,000 or 1,000-2,000 rpm, each with a ramp of 500 rpm·s⁻¹, for 30 seconds to achieve a thickness of ˜200 nm, ˜250 nm, ˜300 nm, ˜400 nm, or ˜600 nm, respectively.

### Example VII

### Deposition of SiO₂ and Au Thin Films

SiO₂ thin films of ˜20 nm thickness were deposited on top of the PMMA thin films at room temperature using an electron-beam evaporator (Ångstrom, USA), at a rate of 1 Å·s⁻¹. This layer was deposited to protect the PMMA from the subsequent indium-zinc oxide (IZO) sputter-deposition. In related experiments, instead of SiO₂ thin films, Au thin films (˜10 nm) were deposited by thermal evaporation (Ångstrom, USA).

### Example VIII

### Deposition of ITO Thin Films

ITO thin films (˜200 nm thickness) were deposited on PI substrates (˜80 μm thickness) using a radio frequency (RF) linear sputtering system (Kenosistec, Italy). The chamber was first evacuated to 5×10−6 Torr, followed by a pre-sputtering phase to cleanse the target and enhance the process reproducibility. Deposition occurred under 1.1×10−3 Torr pressure with an Ar flow of 40 SCCM and a power density of 0.39W·cm⁻². During the deposition, the substrate was moved laterally to ensure uniform deposition.

### Example IX

### Deposition of IZO Thin Films

IZO thin films (˜250 nm thickness) were deposited on the PEN/PMMA/SiO₂ or PEN/PMMA/Au substrates using DC-magnetron sputtering at room temperature using a IZO ceramic target (90 wt. % In₂O₃-10 wt. % ZnO). Specimens were attached onto a metal mask and placed in the chamber, which was then evacuated until the pressure dropped below 5×10⁻⁶ Torr. Ar gas was passed through the gas mass flow controller into the chamber at 8 SCCM. The power supply for the plasma generator was then turned on and the working pressure was varied such that the DC bias was 280-300 V. After comparing different deposition times and measuring the respective film thickness, the deposition rate was determined to be ˜0.25 Å·s⁻¹. Etching of IZO films, as needed, was performed using the Zn—HCl chemical-etching method.

### Example X

### FIB Cutting

Focused ion beam (FIB) cutting of cross-sections was performed using a Helios 600 instrument (ThermoFisher, USA) with all the specimens being in the bent state. The different flexible specimens were carefully wrapped around lab-made acrylic cylindrical mandrels with r ranging from 5 to 10 mm. In each case, the length of the substrate was ˜πr. After sputtering a thin layer of conductive carbon, the mandrels were carefully attached to the FIB stage using carbon tape. Additional copper tapes were used to hold the sample down, as well as to reduce any charging effects. A beam current of 0.46-0.92 nA was used to make the FIB cuts, in cleaning-cross section mode, without any Pt deposition. It took approximately 3-5 minutes to make each FIB cut.

### Example XI

### Characterization

All scanning electron microscope (SEM; Quattro S, ThermoFisher, USA) observations, top view and cross-sectional view, were performed while the specimens were in the bent state. The same procedure as above was used to mount the bent specimens onto the SEM stage.

An optical microscope (Eclipse LV100, Nikon, USA) was used to make top-view observations, and to measure the crack densities while the specimens were in the bent state. The same procedure as above was used to mount the bent specimens onto the optical microscope stage. The number of cracks in an image was divided by the corrected image length, to account for the curvature, and this number is referred to as the crack density. For each r condition, a minimum of three specimens were used for this measurement.

### Example XII

### Strain in Multilayer Bent Device

In a multilayer device, such as f-PSC, bent to radius r, the multilayer strain is given by ε_{ML}=(z−b)/r, where z is the position along thickness, and b is the neutral mechanical plane (zero-strain position), given by:

$$Table 2$$

$$b = \frac{{\sum }_{i = 1}^{n} {E}_{i} {t}_{i} [ {\sum }_{j = 1}^{i} {t}_{j} - \frac{{t}_{i}}{2} ]}{{\sum }_{i = 1}^{n} {E}_{i} {t}_{i}} ,$$

where Eᵢ and tᵢ denote the Young's moduli and thicknesses, respectively, of the individual layers.

### Example XIII

### Embodiments

Aspects of the present disclosure provides a method of inhibiting crack formation in a combination of a flexible film layer and a flexible substrate supporting the flexible film layer, wherein the flexible film layer and the flexible substrate have an elastic mismatch, including providing a flexible interlayer between the flexible film layer and the flexible substrate to form a multilayer combination in series of the flexible film layer, flexible interlayer and flexible substrate, wherein the flexible film layer has a higher Young's modulus (higher stiffness) than the flexible substrate, wherein the flexible interlayer has a Young's modulus lower than the flexible film layer, wherein the flexible interlayer has a targeted thickness, and wherein crack formation of the flexible substrate is reduced compared to crack formation of the flexible substrate directly contacting the flexible film layer, when subjected to stress. According to one aspect, the flexible interlayer has a Young's modulus lower than the flexible film layer and lower than the flexible substrate. According to one aspect, the flexible interlayer has a thickness of greater than about 200 nm. According to one aspect, the flexible interlayer has a thickness from 200 nm to 800 nm. According to one aspect, the flexible interlayer has a thickness of greater than 300 nm. According to one aspect, the flexible interlayer has a thickness from 300 nm to 600 nm. According to one aspect, the flexible film layer includes an electrode layer. According to one aspect, the flexible film layer includes an electrode layer and the flexible interlayer includes a flexible polymer interlayer. According to one aspect, the flexible film layer includes a transparent conductive oxide electrode, the flexible interlayer includes a flexible polymer interlayer and the flexible substrate includes a flexible polymer substrate. According to one aspect, the flexible film layer directly contacts the flexible interlayer which directly contacts the flexible substrate in a multi-layer fashion. According to one aspect, the Young's modulus of the flexible film layer is 2 times, 3 times, 4 times, 5 times, 6 times, 7 times, 8 times, 9 times, 10 times, 11 times, 12 times, 13 times, 14 times, 15 times, 16 times, 17 times, 18 times, 19 times, or 20 times greater than the Young's modulus of the flexible substrate. According to one aspect, the Young's modulus of the flexible substrate layer is from 1.5 to 10 times greater than the Young's modulus of the flexible interlayer. According to one aspect, the flexible film layer includes an indium tin oxide layer or an indium zinc oxide layer. According to one aspect, the flexible substrate includes polyethylene naphthalate, polyethylene terephthalate or polyimide. According to one aspect, the flexible interlayer includes a polymethylmethacrylate interlayer. According to one aspect, the flexible film layer includes an indium tin oxide layer or an indium zinc oxide layer, the flexible substrate includes a polyethylene naphthalate substrate, and the flexible interlayer includes a polymethylmethacrylate interlayer. According to one aspect, the multilayer combination is included within a flexible perovskite solar cell.

According to one aspect, the present disclosure provides a multilayer flexible combination including in series an electrode layer, an interlayer, and a substrate, wherein the electrode layer has a Young's modulus greater than the substrate, and wherein the interlayer has a Young's modulus lower than the electrode layer and lower than the substrate. According to one aspect, the electrode layer contacts the interlayer which contacts the substrate. According to one aspect, electrode layer includes an indium tin oxide electrode or an indium zinc oxide electrode, the interlayer includes polymethylmethacrylate, and the substrate includes polyethylene naphthalate, polyethylene terephthalate or polyimide.

According to one aspect, the present disclosure provides a multilayer flexible perovskite solar cell including in series a top electrode layer, a hole transport layer, a metal halide perovskite layer, an electron transport layer, a bottom electrode layer, an interlayer, and a substrate, wherein the bottom electrode layer has a Young's modulus greater than the substrate, and wherein the interlayer has a Young's modulus lower than the bottom electrode layer and lower than the substrate. According to one aspect, the bottom electrode layer contacts the interlayer which contacts the substrate. According to one aspect, the bottom electrode layer includes an indium tin oxide electrode or an indium zinc oxide electrode, the interlayer includes polymethylmethacrylate, and the substrate comprises polyethylene naphthalate, polyethylene terephthalate or polyimide.

1. A method of inhibiting crack formation in a combination of a flexible film layer and a flexible substrate supporting the flexible film layer, wherein the flexible film layer and the flexible substrate have an elastic mismatch, comprising
providing a flexible interlayer between the flexible film layer and the flexible substrate to form a multilayer combination in series of the flexible film layer, flexible interlayer and flexible substrate,
wherein the flexible film layer has a higher Young's modulus (higher stiffness) than the flexible substrate,
wherein the flexible interlayer has a Young's modulus lower than the flexible film layer,
wherein the flexible interlayer has a targeted thickness, and
wherein crack formation of the flexible substrate is reduced compared to crack formation of the flexible substrate directly contacting the flexible film layer, when subjected to stress.

2. The method of claim 1 wherein the flexible interlayer has a Young's modulus lower than the flexible film layer and lower than the flexible substrate.

3. The method of claim 1 wherein the flexible interlayer has a thickness of greater than about 200 nm.

4. The method of claim 1 wherein the flexible interlayer has a thickness from 200 nm to 800 nm.

5. The method of claim 1 wherein the flexible interlayer has a thickness of greater than 300 nm.

6. The method of claim 1 wherein the flexible interlayer has a thickness from 300 nm to 600 nm.

7. The method of claim 1 wherein the flexible film layer comprises an electrode layer.

8. The method of claim 1 wherein the flexible film layer comprises an electrode layer and the flexible interlayer comprises a flexible polymer interlayer.

9. The method of claim 1 wherein the flexible film layer comprises a transparent conductive oxide electrode, the flexible interlayer comprises a flexible polymer interlayer and the flexible substrate comprises a flexible polymer substrate.

10. The method of claim 1 wherein the flexible film layer directly contacts the flexible interlayer which directly contacts the flexible substrate in a multi-layer fashion.

11. The method of claim 1 wherein the Young's modulus of the flexible film layer is 2 times, 3 times, 4 times, 5 times, 6 times, 7 times, 8 times, 9 times, 10 times, 11 times, 12 times, 13 times, 14 times, 15 times, 16 times, 17 times, 18 times, 19 times, or 20 times greater than the Young's modulus of the flexible substrate.

12. The method of claim 1 wherein the Young's modulus of the flexible substrate layer is from 1.5 to 10 times greater than the Young's modulus of the flexible interlayer.

13. The method of claim 1 wherein the flexible film layer comprises an indium tin oxide layer or an indium zinc oxide layer.

14. The method of claim 1 wherein the flexible substrate comprises a polyethylene naphthalate, polyethylene terephthalate or polyimide.

15. The method of claim 1 wherein the flexible interlayer comprises a polymethylmethacrylate interlayer.

16. The method of claim 1 wherein the 1 wherein the flexible film layer comprises an indium tin oxide layer or an indium zinc oxide layer, the flexible substrate comprises a polyethylene naphthalate substrate, and the flexible interlayer comprises a polymethylmethacrylate interlayer.

17. The method of claim 1 wherein the multilayer combination is comprised within a flexible perovskite solar cell.

18. A multilayer flexible combination comprising in series an electrode layer, an interlayer, and a substrate,
wherein the electrode layer has a Young's modulus greater than the substrate, and
wherein the interlayer has a Young's modulus lower than the electrode layer and lower than the substrate.

19. The multilayer flexible combination of claim 18 wherein the electrode layer contacts the interlayer which contacts the substrate.

20. The multilayer flexible combination of claim 19 wherein the electrode layer comprises an indium tin oxide electrode or an indium zinc oxide electrode, the interlayer comprises polymethylmethacrylate, and the substrate comprises polyethylene naphthalate.

21. A multilayer flexible perovskite solar cell comprising in series a top electrode layer, a hole transport layer, a metal halide perovskite layer, an electron transport layer, a bottom electrode layer, an interlayer, and a substrate,
wherein the bottom electrode layer has a Young's modulus greater than the substrate, and
wherein the interlayer has a Young's modulus lower than the bottom electrode layer and lower than the substrate.

22. The multilayer flexible perovskite solar cell of claim 21 wherein the bottom electrode layer contacts the interlayer which contacts the substrate.

23. The multilayer flexible perovskite solar cell of claim 22 wherein the bottom electrode layer comprises an indium tin oxide electrode or an indium zinc oxide electrode, the interlayer comprises polymethylmethacrylate, and the substrate comprises polyethylene naphthalate.
